(19) United States
(12) Patent Application Publication
(10) Pub. No.: US 2025/0292822 A1
(43) Pub. Date: Sep. 18, 2025

(54) MEMORY DEVICES, OPERATION METHOD THEREOF, AND MEMORY SYSTEM

(71) Applicant: YANGTZE MEMORY TECHNOLOGIES CO., LTD., Wuhan (CN)

(72) Inventors: Zhuohan BU, Wuhan (CN); Jiahao CHEN, Wuhan (CN); Xuesong SHEN, Wuhan (CN)

(21) Appl. No.: 19/049,889

(22) Filed: Feb. 10, 2025

(30) Foreign Application Priority Data
Mar. 13, 2024 (CN) 2024102879977

(51) Int. Cl. G11C 11/4076; G11C 11/4096; H03L 7/081

(52) U.S. Cl. CPC G11C 11/4076; G11C 11/4096; H03L 7/0818

(57) ABSTRACT

A memory device includes: a memory cell array including M bank groups, each of which includes N banks; a peripheral circuit coupled to the memory cell array and configured to: regulate an internal clock signal in response to a first access mode signal and output a first clock signal; output a first data signal in response to the first clock signal and a first local data signal, wherein the first local data signal comprises a plurality of first data periods and a plurality of first interval periods alternating with the plurality of first data periods, and two adjacent ones of the first sampling signals fall respectively in the first data period and the first interval period adjacent to each other; and write the first data signal into a target bank of the (M*N) banks.

### CROSS-REFERENCE TO RELATED APPLICATIONS

This application claims the benefit of priority to China Patent Application No. CN 2024102879977, filed on Mar. 13, 2024, which is incorporated herein by reference in its entirety.

### TECHNICAL FIELD

Implementations of the present disclosure relate to the field of semiconductor technology and in particular to a memory device and an operation method thereof, a memory system and a computer system.

### BACKGROUND

In recent years, the industry of semiconductor integrated circuits has experienced rapid development. With continuous progress of semiconductor manufacturing processes, characteristic sizes of semiconductor devices are continuously reduced, integration densities of memories are becoming higher and performance of memories is increasingly improved. For example, dynamic random access memories (DRAMs), static random access memories (SRAMs) and NAND memories are common semiconductor memory devices used in computers.

### SUMMARY

According to one aspect of the present disclosure provides a memory device including:
a memory cell array including M bank groups, each of which includes N banks, both M and N being integers larger than 1;
a peripheral circuit coupled to the memory cell array and configured to:
   regulate an internal clock signal in response to a first access mode signal and output a first clock signal, wherein the first clock signal includes a plurality of first sampling signals spaced from each other and the first access mode signal is for instructing access to the N banks;
   output a first data signal in response to the first clock signal and a first local data signal, wherein the first local data signal includes a plurality of first data periods and a plurality of first interval periods alternating with the plurality of first data periods and two adjacent ones of the first sampling signals fall respectively in the first data period and the first interval period adjacent to each other; and
   write the first data signal into a target bank of the (M*N) banks.

In some implementations, the internal clock signal includes a plurality of original sampling signals spaced from each other; and the peripheral circuit includes a timing control circuit configured to:
regulate the pulse width of the original sampling signal in response to the first access mode signal; and
output the first clock signal in response to the regulated pulse width of the original sampling signal, wherein the clock cycle of the first clock signal is the same as the clock cycle of the internal clock signal.

In some implementations, the timing control circuit includes:
a clock signal pulse width control circuit configured to reduce the pulse width of the original sampling signal in response to the first access mode signal; and
a clock signal output circuit configured to output the first clock signal in response to the reduced pulse width of the original sampling signal.

In some implementations, the clock signal pulse width control circuit includes: a chopper circuit or a logic gate circuit.

In some implementations, the logic gate circuit includes at least one of an AND gate, a NOR gate, a NOT gate and a NAND gate.

In some implementations, the timing control circuit is further configured to:
regulate the delay time of the original sampling signal in response to the first access mode signal; and
output the first clock signal in response to the regulated delay time of the original sampling signal.

In some implementations, the timing control circuit is further configured to:
regulate the internal clock signal in response to a second access mode signal and output a second clock signal, wherein the second clock signal includes a plurality of second sampling signals spaced from each other and the second access mode signal is for instructing access to the M bank groups;
the peripheral circuit is further configured to: output a second data signal in response to the second clock signal and a second local data signal, wherein the second local data signal includes a plurality of second data periods and a plurality of second interval periods alternating with the plurality of second data periods, the second data period is longer than the first data period, the second interval period is longer than the first interval period, and two adjacent ones of the second sampling signals fall respectively in the second data period and the second interval period adjacent to each other; and
write the second data signal into the target bank group of the M bank groups.

In some implementations, the timing control circuit is configured to:
delay the internal clock signal in response to the second access mode signal; and
output the second clock signal in response to the delayed internal clock signal, wherein the clock cycle of the second clock signal is the same as the clock cycle of the internal clock signal.

In some implementations, the timing control circuit includes:
a clock signal input circuit configured to: output the internal clock signal in response to a bank clock signal and an activating signal.

In some implementations, the memory device includes a 4^{th}-generation double data rate synchronous dynamic random access memory, a 5^{th}-generation double data rate synchronous dynamic random access memory or an external random access memory.

According to another aspect, the present disclosure provides an operation method of a memory device, wherein the memory device includes a memory cell array including M bank groups, each of which includes N banks, both M and N are integers larger than 1, and the operation method includes:
regulating the internal clock signal in response to a first access mode signal and outputting a first clock signal, wherein the first clock signal includes a plurality of first sampling signals spaced from each other and the first access mode signal is for instructing access to the N banks;
outputting a first data signal in response to the first clock signal and a first local data signal, wherein the first local data signal includes a plurality of first data periods and a plurality of first interval periods alternating with the plurality of first data periods, and two adjacent ones of the first sampling signals fall respectively in the first data period and the first interval period adjacent to each other; and
writing the first data signal into a target bank of the (M*N) banks.

In some implementations, the internal clock signal includes a plurality of original sampling signals spaced from each other; and regulating the internal clock signal in response to a first access mode signal and outputting a first clock signal includes:
regulating the pulse width of the original sampling signal in response to the first access mode signal; and
outputting the first clock signal in response to the regulated pulse width of the original sampling signal, wherein the clock cycle of the first clock signal is the same as the clock cycle of the internal clock signal.

In some implementations, regulating the pulse width of the original sampling signal in response to the first access mode signal includes:
reducing the pulse width of the original sampling signal in response to the first access mode signal; and
outputting the first clock signal in response to the regulated pulse width of the original sampling signal includes:
   outputting the first clock signal in response to the reduced pulse width of the original sampling signal.

In some implementations, regulating the internal clock signal in response to a first access mode signal and outputting a first clock signal includes:
regulating the delay time of the original sampling signal in response to the first access mode signal; and
outputting the first clock signal in response to the regulated delay time of the original sampling signal.

In some implementations, the operation method further includes:
regulating the internal clock signal in response to a second access mode signal and outputting a second clock signal, wherein the second clock signal includes a plurality of second sampling signals spaced from each other, and the second access mode signal is for instructing access to the M bank groups;
outputting a second data signal in response to the second clock signal and a second local data signal, wherein the second local data signal includes a plurality of second data periods and a plurality of second interval periods alternating with the plurality of second data periods, the second data period is longer than the first data period, the second interval period is longer than the first interval period, and two adjacent ones of the second sampling signals fall respectively in the second data period and the second interval period adjacent to each other; and
writing the second data signal into the target bank group of the M bank groups.

In some implementations, regulating the internal clock signal in response to a second access mode signal and outputting a second clock signal includes:
delaying the internal clock signal in response to the second access mode signal; and
outputting the second clock signal in response to the delayed internal clock signal, wherein the clock cycle of the second clock signal is the same as the clock cycle of the internal clock signal.

In some implementations, the operation method further includes:
outputting the internal clock signal in response to a bank clock signal and an activating signal.

According to a further aspect, the present disclosure provides a memory system including:
the memory device of any one of the above-described implementations; and
a memory controller coupled to the memory device and configured to control the memory device.

According to a further aspect, the present disclosure provides a computer system including:
the memory system of the above-described implementation; and
a host coupled to the memory system.

In implementations of the present disclosure, the peripheral circuit regulates an internal clock signal in response to a first access mode signal and output a first clock signal; subsequently the peripheral circuit outputs a first data signal in response to the first clock signal and a first local data signal, wherein the first local data signal includes alternating first data periods and first interval periods, and two adjacent ones of the first sampling signals in the first clock signal fall respectively in the first data period and the first interval period adjacent to each other; and finally the peripheral circuit writes the first data signal into the target bank. As such, the peripheral circuit may adjust the timing of an internal clock signal in response to a first access mode signal to satisfy the requirements for write timing in such an access mode that the memory device accesses the banks directly, improving the compatibility of the memory device with various access modes.

### BRIEF DESCRIPTION OF THE DRAWINGS

FIG. 1 is a schematic diagram of a memory device provided in an implementation of the present disclosure;

FIG. 2 is a timing diagram of various signals in a bank group mode of a memory device provided in an implementation of the present disclosure;

FIG. 3 is a timing diagram of various signals in a 16 bank mode of a memory device provided in an implementation of the present disclosure;

FIG. 4 is a schematic diagram of another memory device provided in an implementation of the present disclosure;

FIG. 5 is a timing diagram of various signals in a 16 bank mode of another memory device provided in an implementation of the present disclosure;

FIG. 6 is a schematic diagram of a timing control circuit in another memory device provided in an implementation of the present disclosure;

FIG. 7 is a schematic diagram of a chopper circuit in a timing control circuit provided in an implementation of the present disclosure;

FIG. 8 is a schematic diagram of a logic gate circuit in a timing control circuit provided in an implementation of the present disclosure;

FIG. 9 is a timing diagram of various signals of a logic gate circuit in a timing control circuit provided in an implementation of the present disclosure;

FIG. 10 is a flow chart illustrating operations of an operation method of a memory device provided in an implementation of the present disclosure; and

FIG. 11 is a schematic diagram of a memory system and a computer system provided in an implementation of the present disclosure.

### DETAILED DESCRIPTION

In order to facilitate understanding of the present disclosure, example implementations of the present disclosure will be described in more detail with reference to relevant accompanying drawings. Although example implementations of the present disclosure are illustrated in accompanying drawings, it should be understood that the present disclosure can be embodied in various forms and is not limited to specific implementations described herein. On the contrary, the implementations are provided for more thorough understanding of the present disclosure and to convey the scope the present disclosure fully to those skilled in the art.

In the description hereafter, many specific details are provided to facilitate more thorough understanding of the present disclosure. However, it is apparent for those skilled in the art that the present disclosure can be implemented without one or more of these details. In some implementations, to avoid obscuring the present disclosure, some technical features well known in the art will not be described. That is to say, not all features of practical implementations will be described herein and well-known functions and structures may not be described in detail.

Generally, terms should be understood at least in part from the usage in their contexts. For example, the term “one or more”, as used herein, may be used to describe any feature, structure, or characteristic in a singular sense or may be used to describe combinations of features, structures or characteristics in a plural sense, depending at least in part upon context. Similarly, terms, such as “a,” “an,” or “the,” again, may be understood to convey a singular usage or to convey a plural usage, depending at least in part upon context. In addition, it should be understood that the term “based on” is not necessarily intended to convey an exclusive set of factors and may, instead, allow for existence of additional factors not necessarily described expressly, also depending at least in part on context.

Terminology is used herein only for description of implementations and in no way for limiting the present disclosure, unless defined otherwise. As used herein, the terms “a”, “an” and “the” in singular forms are also intended to cover plural forms, unless the context clearly indicates otherwise. It is also be appreciated that terms “comprise”, “comprising”, “include” and/or “including”, as used in the specification, specify presence of the mentioned features, integers, steps, operations, elements and/or components, but do not exclude presence or addition of one or more other features, integers, steps, operations, elements, components and/or combinations thereof. As used herein, the term “and/or” includes any and all combinations of relevant listed items.

For thorough understanding of the present disclosure, detailed operations and structures will be provided in the following description to set fourth solutions of the present disclosure. Detailed description of implementations of the present disclosure is as follows, however the present disclosure may have other implementations in addition to the detailed description.

In some implementations, memories include, but not limited to, double data rate 4^{th}-generation synchronous DRAMs (DDR4), Double data rate 5^{th} generation synchronous DRAMs (DDR5) or on-chip expanded RAMs (XRAMs) or the like. Here, a memory device includes a memory cell array, which may include a plurality of banks, and a peripheral circuit coupled to the memory cell array. It is to be noted that a memory cell array refers to a set of memory cells arranged in an array and may include multiple sub-arrays and since multiple sub-arrays sharing the same group of word lines (WLs) and the same group bit lines (BLs) constitute a bank, a memory cell array may include a number of banks. Illustratively, the number of banks in a memory device may be 4, 8, 16 or another number.

In order to satisfy requirements for reading rate, writing rate, operating frequency and the like in different use scenarios, the peripheral circuit in a memory device has multiple mode registers disposed therein, which are configured to control different functions, operating modes, etc. of the memory device. For example, the mode registers may control access modes of the memory device including, but not limited to, an 8 bank access mode (8B mode), a 16 bank access mode (16B mode) and a bank group access mode (BG mode), etc. Herein, in the 8 bank access mode and the 16 bank access mode, the peripheral circuit may address and access each bank separately, while in the bank group access mode the peripheral circuit may address and access a bank group consisting of multiple banks. Illustratively, each bank group may include the same number of banks, and compared to the case, in which the peripheral circuit access 16 banks separately in the 16 bank access mode, in the bank group access mode, the peripheral circuit may access 4 bank groups each including 4 banks. It is to be noted that the 16 bank access mode is enabled in a low-speed application scenario (for example, with a frequency lower than or equal to 3200 MHZ) of a memory, while the bank group access mode is enabled in a high-speed application scenario (for example, with a frequency higher than or equal to 3200 MHZ) of a memory.

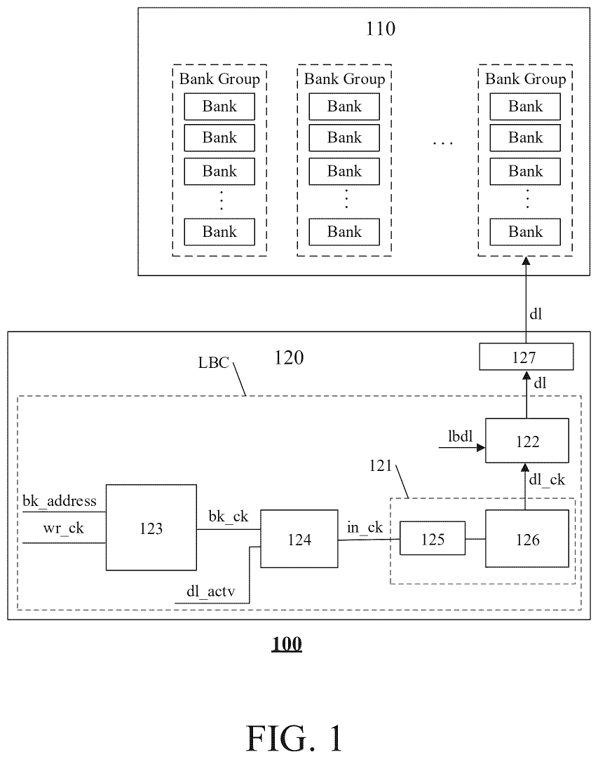

In some implementations, as shown in FIG. 1, the memory device 100 includes a memory cell array 110 and a peripheral circuit 120 coupled to the memory cell array 110. The memory cell array 110 includes M bank groups, each of which includes N banks. Peripheral circuits 120 may include a local bank control (LBC) circuit therein that may generate a data clock signal according to a writing clock signal in the memory device to sample a local data signal and to generate and output a data signal to be written into a target bank. In some examples, with reference to FIG. 1, the LBC circuit includes:

a local bank writing clock generator (Local Bank WR CK Generator) circuit 123 configured to output a bank clock signal bk_ck according to a received bank address bk_address and a writing clock signal wr_ck, wherein the bank address bk_address may be used to indicate a target bank that needs to be written;

a clock signal input (DL CK Generator) circuit 124 coupled to the local bank writing clock generator circuit 123 and configured to receive a bank clock signal bk_ck and output an internal clock signal in_ck according to the bank clock signal bk_ck and an activating signal dl_actv; and a timing control circuit 121 coupled to the clock signal input circuit 124 and configured to regulate the timing (including its pulse width and delay, etc.) of the internal clock signal in_ck and then output a data clock signal dl_ck for data sampling. In some examples, the timing control circuit 121 includes a clock delay circuit 125 (DLY) and a clock signal output circuit 126 (DL CK Widener). The clock delay circuit 125 is coupled to the clock signal input circuit 124 and configured to delay the internal clock signal in_ck. The clock signal output circuit 126 is coupled to the clock delay circuit 125 and configured to adjust the pulse width of the delayed internal clock signal in_ck, for example, increase the pulse width of the internal clock signal in_ck, and then output the data clock signal dl_ck, because the pulse width of the data clock signal, for data sampling, needed by the operation of writing data into the target bank is relatively big and the pulse width the clock signal provided by the peripheral circuit originally is relatively small. Here the data clock signal dl_ck may include a plurality of sampling signals (i.e., the high-level pulses of the data clock signal dl_ck) spaced from each other to enable sampling of a local data signal lbdl; and
a data sampling circuit 122 (Data Sampler) coupled to the clock signal output circuit 126 and configured to sample a local data signal lbdl using the data clock signal dl_ck and then output a data signal dl.

The peripheral circuit 120 may further include a control logic circuit 127 configured to write the data signal dl into the target bank of (M*N) banks.

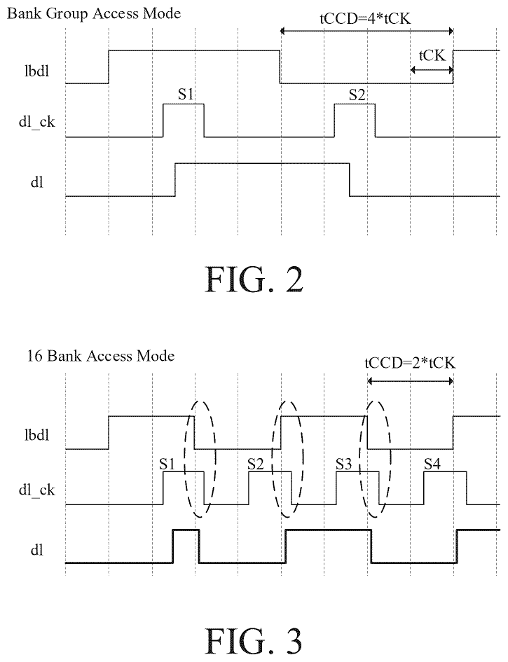

In some implementations, no matter the memory device access mode determined by the mode registers is the 16 bank access mode or the bank group access mode, the local bank control circuit in the peripheral circuit 120 all use the same timing strategy for data sampling. Illustratively, FIG. 2 shows a timing diagram of a local data signal lbdl, a data clock signal dl_ck and a data signal dl in the bank group access mode, wherein the interval period tCCD in the local data signal lbdl under the bank group access mode may be 4 clock cycles tCK (tCK=2.5 ns) and two adjacent ones of the sampling signals (at the high level of the dl_ck) of the data clock signal dl_ck output by the timing control circuit 121 in the peripheral circuit 120 may fall in the data period (at the high level of the lbdl) and the interval period (at the low level of the lbdl) of the local data signal lbdl respectively. It is to be noted that during the sampling signal (i.e., during the high level of the dl_ck), the local data signal lbdl will be sampled continuously. That is to say, during the high level of the dl_ck, if the local data signal lbdl is of a high level, the output data signal dl is of a high level, while if the local data signal lbdl is of a low level, the output data signal dl is of a low level. That is to say, when a previous sampling signal S1 of the data clock signal dl_ck starts (at the rising edge), the high level corresponding to the data period of the local data signal lbdl may be sampled to make the output data signal dl transit from a low level to a high level; when the previous sampling signal S1 of the data clock signal dl_ck ends (at the falling edge), the local data signal lbdl still remains the high level and thus the output data signal dl also remains its high level; when the following sampling signal S2 of the data clock signal dl_ck starts (at the rising edge), the low level corresponding to the interval period of the local data signal lbdl may be sampled to make the output data signal dl transit from the high level to the low level; and when the following sampling signal S2 of the data clock signal dl_ck ends (at the falling edge), the local data signal lbdl still remains the low level and thus the output data signal dl also remains its low level. As such, the data clock signal dl_ck may sample the data of the local data signal lbdl normally in the bank group access mode to generate a correct data signal dl.

FIG. 3 shows a timing diagram of a local data signal lbdl, a data clock signal dl_ck and a data signal dl in the 16 bank access mode, wherein the interval period tCCD in the local data signal lbdl under the bank group access mode may be 2 clock cycles tCK and two adjacent ones of the sampling signals (at the high level of the dl_ck) of the data clock signal dl_ck output by the timing control circuit 121 in the peripheral circuit 120 fail to fall accurately in the data period (at the high level of the lbdl) and the interval period (at the low level of the lbdl) respectively. That is to say, when a first sampling signal S1 of the data clock signal dl_ck starts (at the rising edge), the high level corresponding to the data period of the local data signal lbdl may be sampled to make the output data signal dl transit from a low level to a high level; however, during the first sampling signal S1, the data period of the local data signal lbdl ends and enters the interval period, i.e., the local data signal lbdl transits from the high level to the low level and in turn the output data signal dl transits from its high level to its low level (referring to the first dashed box in FIG. 3); when the first sampling signal S1 ends (at the falling edge), the local data signal lbdl still remains the low level, and in turn the output data signal dl also remains its low level; similarly, when a second sampling signal S2 starts, the local data signal lbdl is at the low level and the data signal dl remains its low level; however, during the second sampling signal S2, the local data signal lbdl transits from the low level to the high level and in turn the output data signal dl transits from its low level to its high level (referring to the second dashed box in FIG. 3); when the second sampling signal S2 ends, the local data signal lbdl is at the high level and the data signal dl remains its high level; until duration of a third sampling signal S3, the local data signal lbdl transits from the high level to the low level and in turn the data signal dl transits from its high level to its low level. As such, the data clock signal dl_ck fails to sample the data of the local data signal lbdl normally in the 16 bank access mode and in turn fails to generate a correct data signal dl.

It can be understood that, the memory device 100 shown in FIG. 1 may use the same timing strategy for data sampling in both the 16 bank access mode and the bank group access mode. Though the memory device 100 may satisfy the requirements for write timing in the bank group access mode and thus perform data sampling normally, errors may occur in data sampling when the memory device 100 is in the 16 bank access mode. Therefore, the memory device 100 has insufficient compatibility with various access modes.

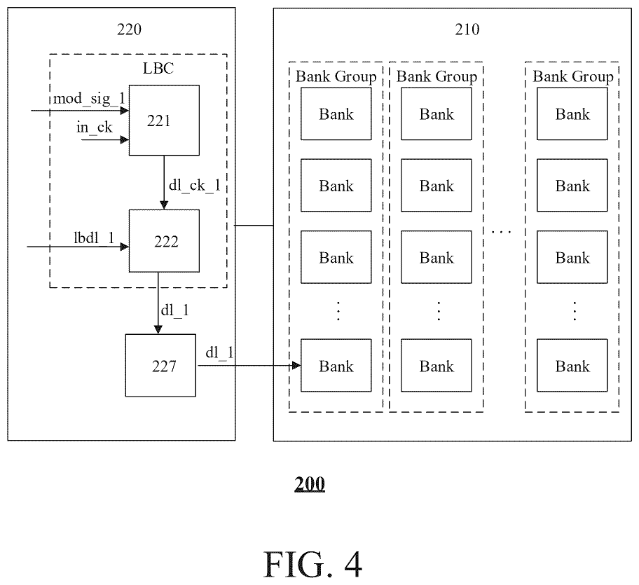

As shown in FIG. 4, the present disclosure provides a memory device 200 including: a memory cell array 210 including M bank groups, each of which includes N banks, both M and N being integers larger than 1; a peripheral circuit 220 coupled to the memory cell array 210 and configured to: regulate an internal clock signal in_ck in response to a first access mode signal mod_sig_1 and output a first clock signal dl_ck_1, wherein the first clock signal dl_ck_1 includes a plurality of first sampling signals spaced from each other and the first access mode signal mod_sig_1 is for instructing access to the N banks; output a first data signal dl_1 in response to the first clock signal dl_ck_1 and a first local data signal lbdl_1, wherein the first local data signal lbdl_1 includes a plurality of first data periods and a plurality of first interval periods alternating with the plurality of first data periods and two adjacent ones of the first sampling signals fall respectively in the first data period and the first interval period adjacent to each other; and write the first data signal dl_1 into a target bank of the (M*N) banks.

In some implementations, the memory device 200 includes a 4^{th}-generation double data rate synchronous dynamic random access memory, a 5^{th}-generation double data rate synchronous dynamic random access memory or an external random access memory.

In an implementation of the present disclosure, the memory device 200 includes a memory cell array 210 and a peripheral circuit 220. The peripheral circuit 220 have a local bank control circuit LBC therein that may generate a data clock signal according to a writing clock signal in the memory device to sample a local data signal and to generate and output a data signal that needs to be written into a target bank. The memory device 200 includes, but not limited to, a 4^{th}-generation double data rate synchronous dynamic random access memory, a 5^{th}-generation double data rate synchronous dynamic random access memory or an external random access memory. It is to be noted that the memory device 200 may be any memory device supporting both the 16 bank access mode and the bank group access mode and there will be no excessive limitation about this.

The local bank control circuit LBC in the peripheral circuit 220 may regulate the internal clock signal in_ck in response to the first access mode signal mod_sig_1 to output a first clock signal dl_ck_1 including a plurality of first sampling signals (at the high level of the dl_ck_1) spaced from each other. Here, the first access mode signal mod_sig_1 may be an instruction signal to be transferred to the mode registers in the peripheral circuit 220. In some examples, the first access mode signal mod_sig_1 may instruct the mode registers to switch the access mode of the memory device to the 16 bank access mode in the above-described implementation. The first access mode signal mod_sig_1 may be a continuous high-level signal. For understanding of the generation process of the internal clock signal in_ck, refer to the implementation corresponding to FIG. 1 and no repetition will be provided here. It is similar to the local data signal lbdl in the above-described implementation that the first local data signal lbdl_1 may include a plurality of first data periods (at the high level of the lbdl_1) and a plurality of first interval periods tCCD (at the low level of the lbdl_1) alternating with the plurality of first data periods, and in the 16 bank access mode each of the first interval periods tCCD may be 2 clock cycles tCK.

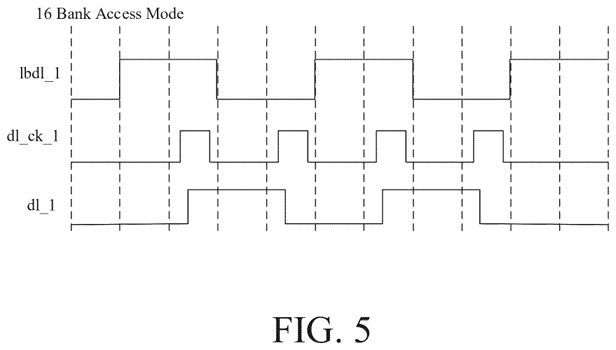

FIG. 5 shows a timing diagram of a first local data signal lbdl_1, a first clock signal dl_ck_1 and a first data signal dl_1 in the 16 bank access mode. The local bank control circuit LBC in the periphery circuits 220 may regulate the delay time, pulse width, etc. of the internal clock signal in_ck in response to the first access mode signal mod_sig_1 to make two adjacent ones of the first sampling signals (at the high level of the dl_ck_1) of the output first data clock signal dl_ck_1 fall in the first data period and the first interval period of the first local data signal lbdl_1 respectively. As such, the first clock signal dl_ck_1 may sample the first local data signal lbdl_1 normally in the 16 bank access mode to generate a correct first data signal dl_1. It is to be noted that the local bank control circuit LBC in the peripheral circuit 220 may include any form of logic circuit to achieve the function of regulating the delay time, pulse width, etc. of the internal clock signal in_ck. The local bank control circuit LBC may further includes a data sampling circuit 222 (Data Sampler) that may sample the first local data signal lbdl_1 using the first clock signal dl_ck_1 and in turn output a first data signal dl_1. The peripheral circuit 220 may further have a control logic circuit 227 (Control Logic) configured to write the first data signal dl_1 into the target bank of the (M*N) banks.

It can be understood that, in the present disclosure, the first access mode signal mod_sig_1 that should have been transferred to the mode registers is guided to the local bank control circuit LBC of the peripheral circuit 220, so that the local bank control circuit LBC may regulate the internal clock signal in_ck in response to the first access mode signal mod_sig_1 and in turn the data of the first local data signal lbdl_1 may be sampled normally in the 16 bank access mode using the output first clock signal dl_ck_1. As such, the peripheral circuit 220 may satisfy the requirements for write timing in such an access mode that the memory accesses the banks directly, improving the compatibility of the memory device with various access modes. It is to be noted that, in the present disclosure, the first access mode signal mod_sig_1 may be input to the mode registers and the bank control circuit LBC simultaneously.

In some implementations, the internal clock signal in_ck includes a plurality of original sampling signals spaced from each other; the peripheral circuit 220 includes a timing control circuit 221 configured to: regulate the pulse width of the original sampling signal in response to the first access mode signal mod_sig_1; and output the first clock signal dl_ck_1 in response to the regulated pulse width of the original sampling signal, wherein the clock cycle of the first clock signal dl_ck_1 is the same as the clock cycle of the internal clock signal in_ck.

In an implementation of the present disclosure, the internal clock signal in_ck includes a plurality of original sampling signals spaced from each other, each of which may be the high level of the internal clock signal in_ck. It is to be noted that, the internal clock signal in_ck and the first clock signal dl_ck_1 have the same clock cycle, a clock cycle referring to a period composed of a portion with a high level and an adjacent portion with a low level in a clock signal. That is to say, the timing control circuit 221 does not adjust the clock cycle of the internal clock signal in_ck.

In some examples, the timing control circuit 221 may be configured to regulate the pulse width of the original sampling signal (i.e., the high level of the in_ck) in the internal clock signal in_ck in response to the first access mode signal mod_sig_1 to make two adjacent ones of the first sampling signals (at the high level of the dl_ck_1) of the output first clock signal dl_ck_1 fall in a first data period and a first interval period of a first clock signal dl_ck_1. It can be understood that the pulse width of the original sampling signal that has been regulated by the timing control circuit 221 is the pulse width of the first sampling signal.

Illustratively, referring to the implementation of FIG. 3, the pulse width of the original sampling signal in the internal clock signal in_ck is the same as that of the sampling signal in the data clock signal dl_ck. That is to say, it is because the pulse width of the original sampling signal in the internal clock signal in_ck is relatively large that if the pulse width of the original sampling signal is not regulated, two adjacent ones of the sampling signals of the data clock signal dl_ck output by the timing control circuit will not fall accurately in the data period (at the high level of the lbdl) and the interval period (at the low level of the lbdl) of a local data signal lbdl. Therefore, referring to FIG. 5, after the pulse width of the original sampling signal in the internal clock signal in_ck is regulated by the timing control circuit 221, two adjacent ones of the first sampling signals of the first clock signal dl_ck_1 output by the timing control circuit 221 can fall accurately in the first data period and the first interval period of a first local data signal lbdl_1, so that the data sampling circuit 222 may use the first clock signal dl_ck_1 to sample the first local data signal lbdl_1 normally and output a first data signal dl_1. As such, the peripheral circuit 220 may satisfy the requirements for write timing in the 16 bank access mode of a memory device, improving the compatibility of the memory device with various access modes.

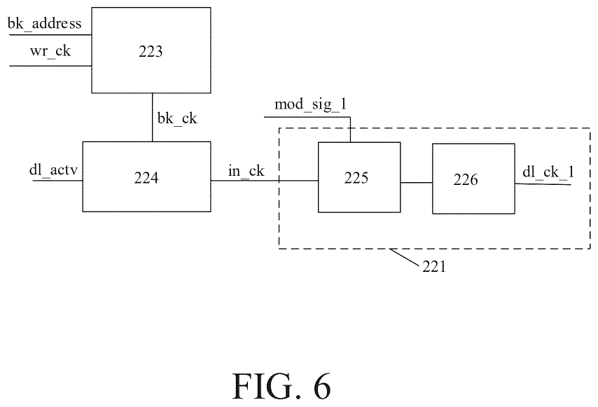

In some implementations, as shown in FIG. 6, the timing control circuit 221 includes: a clock signal pulse width control circuit 225 configured to reduce the pulse width of the original sampling signal in response to the first access mode signal mod_sig_1; and a clock signal output circuit 226 configured to output the first clock signal dl_ck_1 in response to the reduced pulse width of the original sampling signal.

In an implementation of the present disclosure, the timing control circuit 221 includes a clock signal pulse width control circuit 225 and a clock signal output circuit 226. Here, the clock signal pulse width control circuit 225 may reduce the pulse width of the original sampling signal (i.e., at the high level of in_ck) in the internal clock signal in_ck in response to the first access mode signal mod_sig_1, and may be any circuit configured to reduce the pulse width of a clock signal, about which there will be no excessive limitation. The clock signal output circuit 226 (DL CK Widener) may be understood, referring to an implementation corresponding to FIG. 1. The clock signal output circuit 226 may be configured to increase the pulse width of the internal clock signal in_ck significantly, because the pulse width of the first clock signal, which is for data sampling and needed for writing data into a target bank, is relatively large while the pulse width of the clock signal (e.g., a writing clock signal wr_ck) provided by the peripheral circuit originally is relatively small. It can be understood that since the clock signal output circuit 226 is not capable of adjust the pulse width of the internal clock signal in_ck precisely, the present disclosure needs the clock signal pulse width control circuit 225 to reduce the pulse width of the original sampling signal in the internal clock signal in_ck precisely and in turn satisfy the requirements for write timing in the 16 bank access mode.

Therefore, two adjacent ones of the first sampling signals of the first clock signal dl_ck_1 output by the timing control circuit 221 fall in the first data period and the first interval period of a first local data signal lbdl_1, so that the data sampling circuit 222 may use the first clock signal dl_ck_1 to sample the first local data signal lbdl_1 normally to output a first data signal dl_1.

In some implementations, the timing control circuit 221 includes: a clock signal input circuit 224 (DL CK Generator) configured to: output the internal clock signal in_ck in response to a bank clock signal bk_ck and an activating signal dl_actv.

In an implementation of the present disclosure, as shown in FIG. 6, the timing control circuit 221 further includes a clock signal input circuit 224 configured to receive the bank clock signal bk_ck and the activating signal dl_actv and output an internal clock signal in_ck in response to the bank clock signal bk_ck and the activating signal dl_actv. Here, refer to the implementation corresponding to FIG. 1 for understanding of the bank clock signal bk_ck. In some examples, the writing clock generator circuit 223 (Local Bank WR CK Generator) of the timing control circuit 221 is configured to output a bank clock signal bk_ck according to a bank address bk_address and a writing clock signal wr_ck. Here the bank address bk_address may be used to indicate the target bank for a writing operation and in turn the bank clock signal bk_ck may be applied to the operations related to the target bank. And the activating signal dl_actv may control the clock signal input circuit 224 to or not to output the internal clock signal in_ck. It can be understood that in the present disclosure the writing clock signal wr_ck, the bank clock signal bk_ck and the internal clock signal in_ck have the same pulse width, i.e., the pulse width of each of the three signals is not adjusted.

In some implementations, the clock signal pulse width control circuit 225 includes: a chopper circuit or a logic gate circuit.

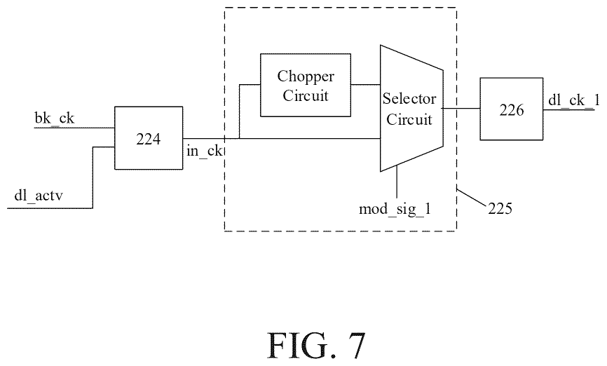

In an implementation of the present disclosure, as shown in FIG. 7, the clock signal pulse width control circuit 225 may include a chopper circuit CK_Width_Chopper that may reduce the pulse width of the original sampling signal (i.e., at the high level of the in_ck) in the internal clock signal in_ck. In some examples, the clock signal pulse width control circuit 225 includes a chopper circuit CK_Width_Chopper and a selector circuit MUX, wherein the two input terminals of the selector circuit MUX are connected to the chopper circuit CK_Width_Chopper and the clock signal input circuit 224 respectively and the selecting terminal of the selector circuit MUX is configured to receive the first access mode signal mod_sig_1. As such, the chopper circuit CK_Width_Chopper may output a clock signal with a pulse width reduced thereby, i.e., the first clock signal dl_ck_1, when having received the first access mode signal mod_sig_1 (with a high level at the input terminal), or the chopper circuit may output the internal clock signal in_ck, i.e., without reducing the pulse width of the original sampling signal in the internal clock signal in_ck, when receiving no first access mode signal mod_sig_1 (with a low level at the input terminal).

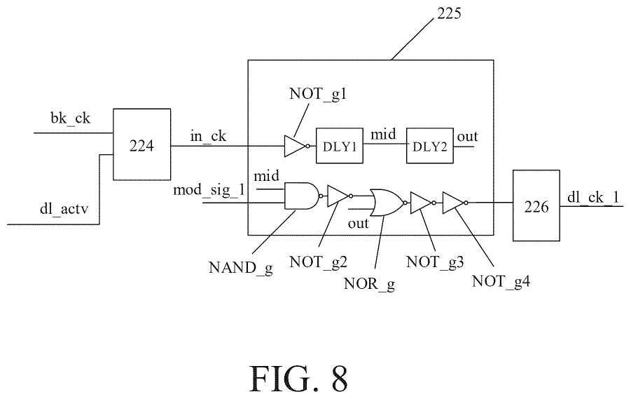

As shown in FIG. 8, the clock signal pulse width control circuit 225 may further include a logic gate circuit and perform various logical operations on the first access mode signal mod_sig_1 and the internal clock signal in_ck to reduce the pulse width of each original sampling signal in the internal clock signal in_ck and in turn output a first clock signal dl_ck_1 with an appropriate pulse width.

In some implementations, the logic gate circuit includes at least one of an AND gate, a NOR gate, a NOT gate and a NAND gate.

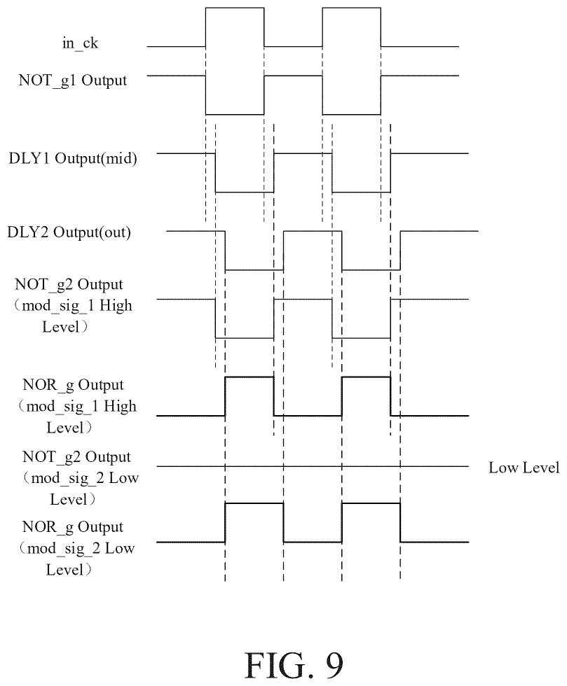

In an implementation of the present disclosure, the logic gate circuit in the clock signal pulse width control circuit 225 includes, but not limited to, at least one of an AND gate, a NOR gate, a NOT gate and a NAND gate. In some examples, as shown in FIG. 8, the logic gate circuit in the clock signal pulse width control circuit 225 is constituted by all of a first inverter NOT_g1, a first delay circuit DLY1, a second delay circuit DLY2, a NAND gate NAND_g, a second inverter NOT_g2, a NOR gate NOR_g, a third inverter NOT_g3 and a fourth inverter NOT_g4. Here, the input terminal of the first inverter NOT_g1 is configured to receive the internal clock signal in_ck, one of the input terminals of the NAND gate NAND_g is configured to receive the first access mode signal mod_sig_1, and the fourth inverter NOT_g4 is configured to output the first clock signal dl_ck_1 with a regulated pulse width. Reference could be made to the timing shown in FIG. 9 for understanding of the process of reducing the pulse width of the original sampling signal in the internal clock signal in_ck by the logic gate circuit. It is to be noted that since the last two inverters, i.e., the third inverter NOT_g3 and the fourth inverter NOT_g4, do not regulate the pulse width of the clock signal and the clock signal is not inverted in level after passing through the third inverter NOT_g3 and the fourth inverter NOT_g4, FIG. 9 only shows the timing of the output signal of the NOR gate NOR_g. It can be seen that if the NAND gate NAND_g receives no first access mode signal mod_sig_1 (i.e., with a low level at the input terminal), the clock signal output by the NOR gate NOR_g has a relatively large pulse width, i.e., the pulse width of the clock signal output by the NOR gate NOR_g is the same as that of the internal clock signal in_ck without being reduced; if the NAND gate NAND_g receives the first access mode signal mod_sig_1 (i.e., with a high level at the input terminal), the clock signal output by the NOR gate NOR_g has a reduced pulse width to make two adjacent ones of the first sampling signals of the finally output first clock signal dl_ck_1 fall in the first data period and the first interval period of a first local data signal lbdl_1 respectively.

In some implementations, the timing control circuit 221 is further configured to: regulate the delay time of the original sampling signal in response to the first access mode signal mod_sig_1; and output the first clock signal dl_ck_1 in response to the regulated delay time of the original sampling signal.

In an implementation of the present disclosure, the timing control circuit 221 may regulate the delay time of the original sampling signal in the internal clock signal in_ck in response to the first access mode signal mod_sig_1. As such, although the timing control circuit 221 does not regulate the pulse width of the original sampling signal in the internal clock signal in_ck, the timing control circuit 221, by regulating the delay time of the internal clock signal in_ck, may also make two adjacent ones of the first sampling signals of the output first clock signal dl_ck_1 fall in the first data period and the first interval period of a first local data signal lbdl_1, satisfying the requirements for write timing in the 16 bank access mode of the memory device 200.

In some implementations, the timing control circuit 221 may also regulate the delay time and the pulse width of the original sampling signal (i.e., the high level of the in_ck) in the internal clock signal in_ck at the same time in response to the first access mode signal mod_sig_1 to make two adjacent ones of the first sampling signals of the output first clock signal dl_ck_1 fall in a first data period and a first interval period of a first clock signal dl_ck_1.

In some implementations, the timing control circuit 221 is further configured to: regulate the internal clock signal in_ck in response to a second access mode signal and output a second clock signal, wherein the second clock signal includes a plurality of second sampling signals spaced from each other and the second access mode signal is for instructing access to the M bank groups; the peripheral circuit is further configured to: output a second data signal in response to the second clock signal and a second local data signal, wherein the second local data signal includes a plurality of second data periods and a plurality of second interval periods alternating with the plurality of second data periods, the second data period is longer than the first data period, the second interval period is longer than the first interval period, and two adjacent ones of the second sampling signals fall respectively in the second data period and the second interval period adjacent to each other; and write the second data signal into the target bank group of the M bank groups.

In an implementation of the present disclosure, the timing control circuit 221 may further regulate the internal clock signal in_ck in response to a second access mode signal and output a second clock signal. Here, the second access mode signal may instruct the mode registers to switch the access mode of the memory device to the bank group access mode in the above-described implementations and the second access mode signal may be a continuous low level signal. It is similar to the first local data signal in the above-described implementation that the second local data signal may include a plurality of second data periods (at a high level) and a plurality of second interval periods tCCD (at a low level) alternating with the plurality of second data periods, and in the bank group access mode each of the second interval periods tCCD may be 4 clock cycles tCK. It can be understood that the second interval period in the bank group access mode is longer than the first interval period in the 16 bank access mode, and the second data period in the bank group access mode is longer than the first data period in the 16 bank access mode. The second clock signal includes a plurality of second sampling signals (i.e., at the high level of the second clock signal) spaced from each other, and the data clock signals dl_ck in FIGS. 2 and 3 may be referred to respectively for understanding of the timing of the second clock signal and the timing of the first clock signal.

FIG. 2 may be referred to for understanding the timing of the second local data signal, the timing of the second clock signal and the timing of the second data signal, wherein the second local data signal, the second clock signal and the second data signal correspond to the local data signal lbdl, the data clock signal dl_ck and the data signal dl in FIG. 2 respectively. That is to say, the timing control circuit 221 may also regulate the internal clock signal in_ck to output the second clock signal and to make two adjacent ones of the second sampling signals of the second clock signal fall respectively in the second data period and the second interval period adjacent to each other, so that the requirements for write timing of the memory device 200 in the bank group access mode is satisfied and the compatibility of the memory device with various access modes is improved.

In some implementations, the timing control circuit 221 is configured to: delay the internal clock signal in response to the second access mode signal; and output the second clock signal in response to the delayed internal clock signal, wherein the clock cycle of the second clock signal is the same as the clock cycle of the internal clock signal.

In an implementation of the present disclosure, referring to the logic circuit shown in FIG. 8, the timing control circuit 221 may delay the internal clock signal in_ck in response to a second access mode signal (at the low level continuously) to output the second clock signal. In some examples, in FIG. 8, the input terminal of the first inverter NOT_g1 is configured to receive the internal clock signal in_ck, one of the input terminals of the NAND gate NAND_g is configured to receive the second access mode signal mod_sig_2, and the fourth inverter NOT_g4 is configured to output the second clock signal dl_ck_2. Refer to the timing shown in FIG. 9, when the second access mode signal is a continuous low level signal (corresponding to the case that the NAND gate NAND_g receives no first access mode signal in the above-described implementation), the pulse width of the finally output second clock signal dl_ck_2 is not reduced, i.e., the second clock signal is only obtained by delaying the internal clock signal in_ck, so that the clock cycle of the second clock signal is the same as that of the internal clock signal in_ck.

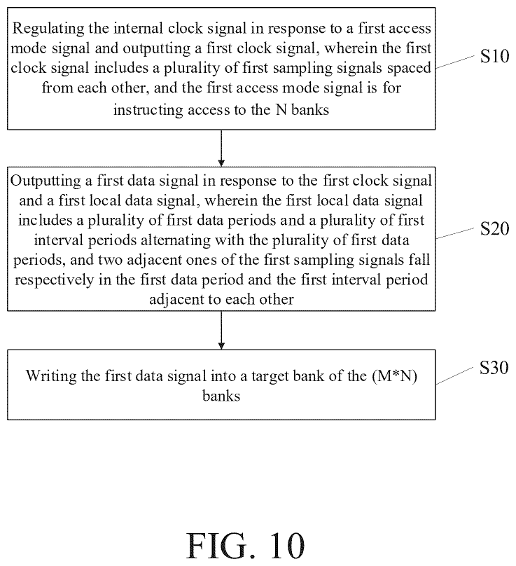

As shown in FIG. 10, the present disclosure provides an operation method of a memory device including a memory cell array. The memory cell array includes M bank groups, each of which includes N banks with both M and N being integers larger than 1. The operation method includes the following operations:
operation S10: regulating the internal clock signal in response to a first access mode signal and outputting a first clock signal, wherein the first clock signal includes a plurality of first sampling signals spaced from each other and the first access mode signal is for instructing access to the N banks;
operation S20: outputting a first data signal in response to the first clock signal and a first local data signal, wherein the first local data signal includes a plurality of first data periods and a plurality of interval periods alternating with the plurality of first data periods, and two adjacent ones of the first sampling signals fall in the first data period and the first interval period adjacent to each other respectively; and
operation S30: writing the first data signal into a target bank of the (M*N) banks.

It should be understood that the operations shown in FIG. 10 are not exclusive and other operation(s) may be performed before, after or between any operation(s) in the shown operations.

It can be understood that in the present disclosure the internal clock signal is regulated in response to a first access mode signal, so that data of a first local data signal may be sampled normally in the 16 bank access mode using the output first clock signal. As such, the peripheral circuit may satisfy the requirements for write timing in such an access mode that the memory accesses the banks directly, improving the compatibility of the memory device with various access modes.

In some implementations, the internal clock signal includes a plurality of original sampling signals spaced from each other; regulating the internal clock signal in response to a first access mode signal and outputting a first clock signal includes: regulating the pulse width of the original sampling signal in response to the first access mode signal; and outputting the first clock signal in response to the regulated pulse width of the original sampling signal, wherein the clock cycle of the first clock signal is the same as the clock cycle of the internal clock signal.

In some implementations, regulating the pulse width of the original sampling signal in response to the first access mode signal includes: reducing the pulse width of the original sampling signal in response to the first access mode signal; and outputting the first clock signal in response to the regulated pulse width of the original sampling signal includes: outputting the first clock signal in response to the reduced pulse width of the original sampling signal.

In some implementations, regulating the internal clock signal in response to the first access mode signal and outputting a first clock signal includes: regulating the delay time of the original sampling signal in response to the first access mode signal; and outputting the first access mode signal in response to the regulated delay time of the original sampling signal.

In some implementations, the operation method further includes: regulating the internal clock signal in_ck in response to a second access mode signal and outputting a second clock signal, wherein the second clock signal includes a plurality of second sampling signals spaced from each other, and the second access mode signal is for instructing access to the M bank groups; outputting a second data signal in response to the second clock signal and a second local data signal, wherein the second local data signal includes a plurality of second data periods and a plurality of second interval periods alternating with the plurality of second data periods, the second data period is longer than the first data period, the second interval period is longer than the first interval period, and two adjacent ones of the second sampling signals fall respectively in the second data period and the second interval period adjacent to each other; and writing the second data signal into the target bank group of the M bank groups.

In some implementations, regulating the internal clock signal in response to a second access mode signal and outputting a second clock signal includes: delaying the internal clock signal in response to the second access mode signal; outputting the second clock signal in response to the delayed internal clock signal, wherein the clock cycle of the second clock signal is the same as the clock cycle of the internal clock signal.

In some implementations, the operation method further includes: outputting the internal clock signal in response to a bank clock signal and an activating signal.

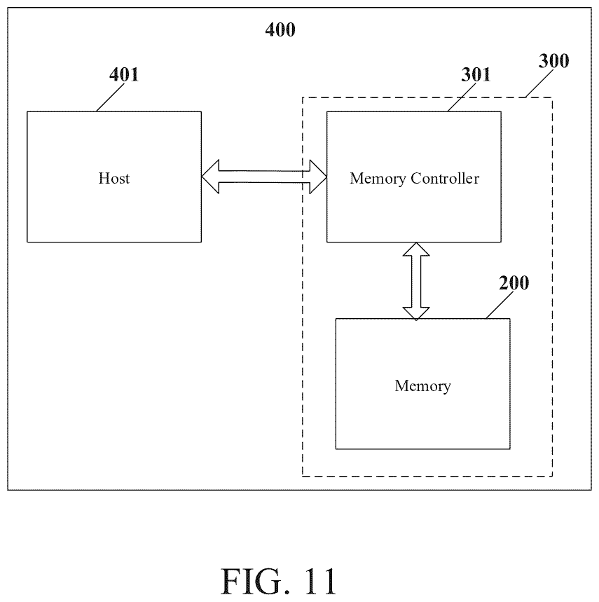

As shown in FIG. 11, the present disclosure provides a memory system 300 including: the memory device 200 in any one of the above-described implementations; and a memory controller 301 coupled to the memory device 200 and configured to control the memory device 200.

In an implementation of the present disclosure, the memory controller 301 is coupled to the memory device 200 and configured to control the memory device 200 to perform operations such as reading and writing. The memory controller 301 may include a processor, a microcontroller, a field programmable gate array (FPGA), an application specific integrated circuit (ASIC) or the like therein.

As shown in FIG. 11, the present disclosure provides a computer system 400 including: the memory system 300 in the above-described implementation; and a host 401 coupled to the memory system 300.

In an implementations of the present disclosure, the host 401 may be a processor of an electronic apparatus, such as a central processing unit (CPU), or a system-on-chip (SOC) such as an application processor (AP). The host 401 may be configured to send data to the memory system 300 or receive data from the memory system 300.

It can be understood that in the present disclosure the internal clock signal is regulated in response to a first access mode signal, so that data of a first local data signal may be sampled normally in the 16 bank access mode using the output first clock signal. As such, the peripheral circuit may satisfy the requirements for write timing in such an access mode that the memory accesses the banks directly, improving the compatibility of the memory device with various access modes.

It can be understood that “one implementation” or “an implementation” mentioned throughout the specification means that particular features, structures or characteristics in association with the implementation are included in at least one implementation of the present disclosure. Therefore, “in one implementation” or “in an implementation” mentioned throughout the specification refers not necessarily to the same implementation. Moreover, those particular features, structures or characteristics may be incorporated in one or more implementations in any suitable manner. It can be understood that, in various implementations of the present disclosure, the ordinal numbers of the various processes above-mentioned are not intended to indicate that the processes must be performed in any sequential order, and the various processes should be performed in a sequential order determined depending on their functions and inherent logic, which do not constitute any limitation on the implementation process of implementations of the present disclosure. The ordinal numbers in the above-mentioned implementations of the present disclosure are only for the purpose of description and imply no preference for any one or more implementations over the others.

Only implementations of the present disclosure are described above. It is not intended to limit the scope claimed by the present disclosure. All the equivalent structural transformations obtained using the contents of the specification and accompanying drawings in the present disclosure following the inventive concept of the present disclosure or direct/indirect application of the inventive concept in other related technical fields fall within the scope claimed by the present disclosure.

What is claimed is:

1. A memory device, comprising:
a memory cell array comprising M bank groups, each of which comprises N banks, both M and N being integers larger than 1;
a peripheral circuit coupled to the memory cell array and configured to:
regulate an internal clock signal in response to a first access mode signal and output a first clock signal, wherein the first clock signal comprises a plurality of first sampling signals spaced from each other, and the first access mode signal is for instructing access to the N banks;
output a first data signal in response to the first clock signal and a first local data signal, wherein the first local data signal comprises a plurality of first data periods and a plurality of first interval periods alternating with the plurality of first data periods, and two adjacent ones of the first sampling signals fall respectively in the first data period and the first interval period adjacent to each other; and
write the first data signal into a target bank of the (M*N) banks.

2. The memory device of claim 1, wherein the internal clock signal comprises a plurality of original sampling signals spaced from each other, and the peripheral circuit comprises a timing control circuit configured to:
regulate a pulse width of the original sampling signal in response to the first access mode signal; and
output the first clock signal in response to the regulated pulse width of the original sampling signal, wherein a clock cycle of the first clock signal is the same as a clock cycle of the internal clock signal.

3. The memory device of claim 2, wherein the timing control circuit comprises:
a clock signal pulse width control circuit configured to reduce the pulse width of the original sampling signal in response to the first access mode signal; and
a clock signal output circuit configured to output the first clock signal in response to the reduced pulse width of the original sampling signal.

4. The memory device of claim 3, wherein the clock signal pulse width control circuit comprises: a chopper circuit or a logic gate circuit.

5. The memory device of claim 4, wherein the logic gate circuit comprises at least one of an AND gate, a NOR gate, a NOT gate and a NAND gate.

6. The memory device of claim 2, wherein the timing control circuit is further configured to:
regulate a delay time of the original sampling signal in response to the first access mode signal; and
output the first clock signal in response to the regulated delay time of the original sampling signal.

7. The memory device of claim 2, wherein the timing control circuit is further configured to:
regulate the internal clock signal in response to a second access mode signal and output a second clock signal, wherein the second clock signal comprises a plurality of second sampling signals spaced from each other, and the second access mode signal is for instructing access to the M bank groups;
the peripheral circuit is further configured to: output a second data signal in response to the second clock signal and a second local data signal, wherein the second local data signal comprises a plurality of second data periods and a plurality of second interval periods alternating with the plurality of second data periods, the second data period is longer than the first data period, the second interval period is longer than the first interval period, and two adjacent ones of the second sampling signals fall respectively in the second data period and the second interval period adjacent to each other; and
write the second data signal into a target bank group of the M bank groups.

8. The memory device of claim 7, wherein the timing control circuit is configured to:
delay the internal clock signal in response to the second access mode signal; and
output the second clock signal in response to the delayed internal clock signal, wherein a clock cycle of the second clock signal is the same as a clock cycle of the internal clock signal.

9. The memory device of claim 2, wherein the timing control circuit comprises:
a clock signal input circuit configured to: output the internal clock signal in response to a bank clock signal and an activating signal.

10. The memory device of claim 1, wherein the memory comprises a 4^{th}-generation double data rate synchronous dynamic random access memory, a 5^{h}-generation double data rate synchronous dynamic random access memory or an external random access memory.

11. An operation method of a memory device, wherein the memory device comprises a memory cell array comprising M bank groups, each of which comprises N banks, both M and N are integers larger than 1, and the operation method comprises:
regulating an internal clock signal in response to a first access mode signal and outputting a first clock signal, wherein the first clock signal comprises a plurality of first sampling signals spaced from each other, and the first access mode signal is for instructing access to the N banks;
outputting a first data signal in response to the first clock signal and a first local data signal, wherein the first local data signal comprises a plurality of first data periods and a plurality of first interval periods alternating with the plurality of first data periods, and two adjacent ones of the first sampling signals fall respectively in the first data period and the first interval period adjacent to each other; and
writing the first data signal into a target bank of the (M*N) banks.

12. The operation method of claim 11, wherein the internal clock signal comprises a plurality of original sampling signals spaced from each other, and regulating the internal clock signal in response to the first access mode signal and outputting the first clock signal comprises:
regulating a pulse width of the original sampling signal in response to the first access mode signal; and
outputting the first clock signal in response to the regulated pulse width of the original sampling signal, wherein a clock cycle of the first clock signal is the same as a clock cycle of the internal clock signal.

13. The operation method of claim 12, wherein regulating the pulse width of the original sampling signal in response to the first access mode signal comprises:
reducing the pulse width of the original sampling signal in response to the first access mode signal; and
outputting the first clock signal in response to the regulated pulse width of the original sampling signal comprises:
outputting the first clock signal in response to the reduced pulse width of the original sampling signal.

14. The operation method of claim 12, wherein regulating the internal clock signal in response to the first access mode signal and outputting the first clock signal comprises:
regulating a delay time of the original sampling signal in response to the first access mode signal; and
outputting the first clock signal in response to the regulated delay time of the original sampling signal.

15. The operation method of claim 12, further comprising:
regulating the internal clock signal in response to a second access mode signal and outputting a second clock signal, wherein the second clock signal comprises a plurality of second sampling signals spaced from each other, and the second access mode signal is for instructing access to the M bank groups;
outputting a second data signal in response to the second clock signal and a second local data signal, wherein the second local data signal comprises a plurality of second data periods and a plurality of second interval periods alternating with the plurality of second data periods, the second data period is longer than the first data period, the second interval period is longer than the first interval period, and two adjacent ones of the second sampling signals fall respectively in the second data period and the second interval period adjacent to each other; and
writing the second data signal into a target bank group of the M bank groups.

16. The operation method of claim 15, wherein regulating the internal clock signal in response to the second access mode signal and outputting the second clock signal comprises:
delaying the internal clock signal in response to the second access mode signal; and
outputting the second clock signal in response to the delayed internal clock signal, wherein a clock cycle of the second clock signal is the same as a clock cycle of the internal clock signal.

17. The operation method of claim 12, further comprising:
outputting the internal clock signal in response to a bank clock signal and an activating signal.

18. A memory system, comprising:
a memory device, comprising:
a memory cell array comprising M bank groups, each of which comprises N banks, both M and N being integers larger than 1;
a peripheral circuit coupled to the memory cell array and configured to:
regulate an internal clock signal in response to a first access mode signal and output a first clock signal, wherein the first clock signal comprises a plurality of first sampling signals spaced from each other, and the first access mode signal is for instructing access to the N banks;
output a first data signal in response to the first clock signal and a first local data signal, wherein the first local data signal comprises a plurality of first data periods and a plurality of first interval periods alternating with the plurality of first data periods, and two adjacent ones of the first sampling signals fall respectively in the first data period and the first interval period adjacent to each other; and
write the first data signal into a target bank of the (M*N) banks; and
a memory controller coupled to the memory device and configured to control the memory device.

19. The memory system of claim 18, wherein the internal clock signal comprises a plurality of original sampling signals spaced from each other, and the peripheral circuit comprises a timing control circuit configured to:
regulate a pulse width of the original sampling signal in response to the first access mode signal; and
output the first clock signal in response to the regulated pulse width of the original sampling signal, wherein a clock cycle of the first clock signal is the same as a clock cycle of the internal clock signal.

20. The memory system of claim 19, wherein the timing control circuit comprises:
a clock signal pulse width control circuit configured to reduce the pulse width of the original sampling signal in response to the first access mode signal; and
a clock signal output circuit configured to output the first clock signal in response to the reduced pulse width of the original sampling signal;
wherein the clock signal pulse width control circuit comprises: a chopper circuit or a logic gate circuit.
